(19) United States
(12) Patent Application Publication
(10) Pub. No.: US 2005/0200408 A1
(43) Pub. Date: Sep. 15, 2005

(54) Method and apparatus for feed forward linearization of wideband RF amplifiers

(76) Inventors: James A. Benjamin, Verona, NJ (US); Kenneth H. Abrahamsen, New Milford, NJ (US); Peter J. Donegan, Montclair, NJ (US); Richard P. Morgese, Bardonia, NY (US)

Correspondence Address: DAVID L. DAVIS, ESQ., 90 WASHINGTON VALLEY ROAD, BEDMINSTER, NJ, 07921, US

(21) Appl. No.: 10/801,008

(22) Filed: Mar. 15, 2004

(51) Int. Cl. H03F 1/26

(52) U.S. Cl. 330/149

(57) ABSTRACT

A method and apparatus for providing a linearized wideband RF amplifier includes processing the RF output signal from the amplifier to obtain a carrier-free processed signal of 180° phase inverted distortion products in the RF output signal, whereby the processed signal is amplified and summed with the distorted output signal from an associated power amplifier for removing the distortion products from the RF output signal.

### FIELD OF THE INVENTION

The present invention relates generally to RF amplifiers and, more particularly, to the linearization of broadband RF amplifiers.

### BACKGROUND OF THE INVENTION

As is known to those of skill in the art, all electronic amplifiers generate distortion products to varying degrees. As an amplifier is driven harder by high-level input signals, the level of the distortion products typically increases. Over the years, extensive development work has been pursued for reducing the generation of distortion products in amplifiers. One known technique is to utilize what is known as “feed forward linearization” for reducing the level of the distortion products by amplifying only those products and feeding them forward, with adjustments in their amplitude and phase, for later summing with the amplified input signal including amplified distortion products, whereby the feed forward distortion products cancel a portion of the higher level distortion products in the output signal. This technique, as presently developed, requires the use of notch filters in certain applications, and operates satisfactorily when applied for use with narrowband RF amplifiers, but is not practical for use with wideband RF amplifiers. Also, this technique requires the use of high power error amplifiers. There is therefore a need in the art to improve known techniques for reducing distortion products in power amplifiers in a manner useful over a very wide range of frequencies, and for reducing the power required by error amplifiers.

### SUMMARY OF THE INVENTION

The present invention provides linearization of a broadband radio frequency (RF) amplifier by including “Alpha Loop means” for removing the carrier wave of an input signal for the purpose of obtaining a signal that only includes the distortion products. “Gamma Loop” means are included for providing further electronic filtering, for extracting the carrier wave and data from the combined output of carrier and data of the amplifier, for providing a reference signal for “Beta Loop” means to compare distortion products in the processed signal, as amplified and phase inverted, with the actual distorted and amplified output signal, for summing the distorted signal and its carrier with the weighted and phase inverted processed distortion products, for over a wide range of frequencies effectively canceling the distortion products, including even relatively low level distortion products, to thereby provide an output signal representative of the undistorted input signal or data with carrier.

### BRIEF DESCRIPTION OF THE DRAWINGS

Various embodiments of the present invention are described and illustrated in association with the drawings, in which like items are identified by the same reference designation, wherein:

FIG. 1 is a block schematic diagram of a known two-loop feed forward (FF) linearized RF amplifier;

FIG. 2 shows an undistorted two-tone input signal;

FIG. 3 shows a distorted output signal obtained by amplifying the input signal of FIG. 2 via a non-linear amplifier;

FIG. 4 shows the resultant waveform obtained from passing the input signal through an Alpha Loop, thereby substantially removing the carrier wave, and leaving only the waveforms of distortion products;

FIG. 5 shows the output signal obtained by using a Beta Loop for summing the distorted amplified input signal with weighted and phase adjusted distortion products, for obtaining an amplified signal having reduced distortion;

FIG. 6 shows a block schematic diagram for one embodiment of the present invention for providing a linearized RF amplifier including an “Alpha Loop”, a “Gamma Loop” and a “Beta Loop”, for providing a linear amplifier that can be operated at full power from 20 MHz to 2 GHz, including all bands of legacy radios, in a substantially distortion free manner; and

FIG. 7 shows an example of the Gamma Loop Error typically obtained from the circuit of FIG. 6.

### DETAILED DESCRIPTION

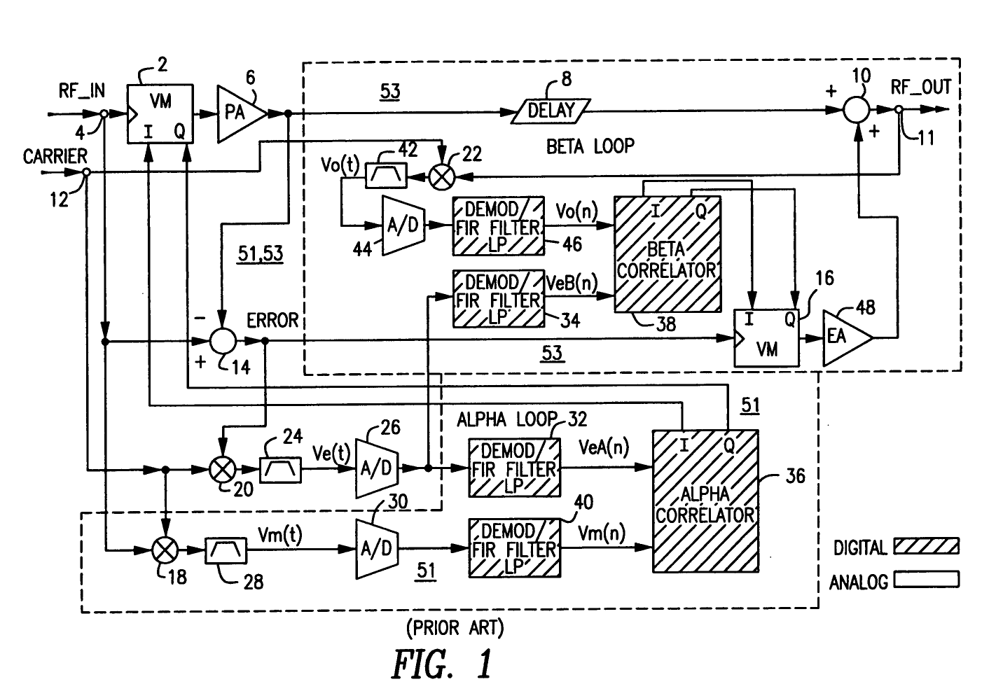

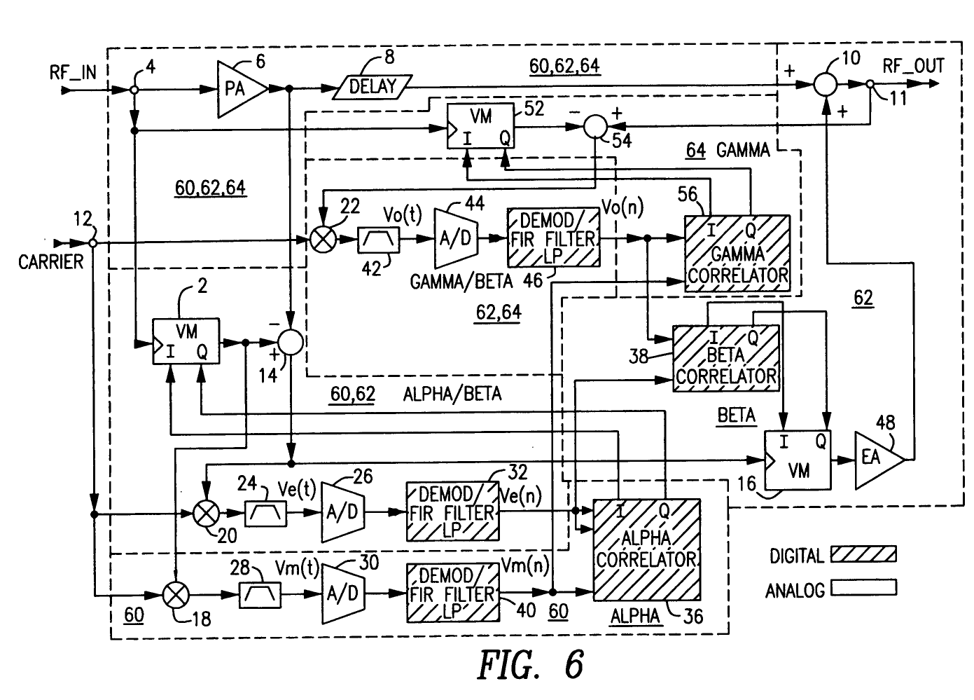

As previously discussed, attempts have been made in the prior art to linearize RF amplifiers. In FIG. 1, a known two- loop Feed Forward (FF) linearized RF amplification system is shown. The operation and design of this system will first be discussed generally, and then followed by more specific details. The two loops include an Alpha Loop 51 and a Beta Loop 53, as shown in dashed boxes. Components outside of the boxes 51 and 53 are shared by each Loop 51, 53. More specifically, the amplification system utilizes digital processing via components shown in crosshatch and analog processing via components shown without any crosshatching. Note that the known amplification system, and the present improved system of FIG. 6 (discussed below in detail) can be completely analog, whereby the digital portions shown are replaced by their analog equivalents. The known system of FIG. 1 includes a Vector Modulator 2 for impressing digital information, received on its in-phase signal input “I” and its quadrature signal input “Q,” upon the RF input signal received on input terminal 4. The output of the Vector Modulator 2 is amplified through a power amplifier 6, which distorts the signal, which is then passed through a delay circuit 8, for delaying the arrival of the signal at a summer 10. Note that the “RF_IN” RF input signal at terminal 4 includes both a carrier wave and a data signal modulating the carrier wave, in this example. Another input terminal 12 receives only the carrier wave. Also, the delay circuit 8 can be included within power amplifier 6.

The output signal from power amplifier 6 is also connected to an inverting input of a summer 14, whereby the output signal is subtracted in this case from the RF input signal applied to terminal 4. The output of the summer 14 is an error signal that is provided as an input signal to another Vector Modulator 16.

The RF input signal is also fed from terminal 4 to a multiplier 18. The carrier signal is used to down convert the various RF modulated signals to a constant IF. The carrier signal appearing at terminal 12 is connected as an input to three multipliers 18, 20 and 22. The output error signal from summer 14 is connected to individual inputs of Vector Multiplier 16 and multiplier 20. The output of multiplier 20 is passed through a band pass filter 24, and the output Ve(t), which is an IF modulated signal, of filter 24 is connected to an analog-to- digital (A/D) converter 26. Similarly, the output of multiplier 18 is passed through a band pass filter 28 to provide an IF Modulated output signal Vm(t) that is connected to the input of analog-to-digital converter 30.

The digitized output from A/D 26 is connected as an input signal to both Demodulator/Finite Impulse Response Low Pass Filters 32, 34 which perform quadrature demodulation on the signals and output the complex, baseband signals VeA(n), VeB(n), respectively. The signals VeA(n) and VeB(n) are provided as input signals to an Alpha Correlator 36 and a Beta Correlator 38, respectively, which are both complex correlators. The digitized Alpha signal from A/D 30 is passed through a Demodulator/Finite Impulse Response Low Pass Filter 40, which performs quadrature demodulation on the signals and outputs the complex, baseband digital signal Vm(n) as another input signal to the Alpha Correlator 36. The in-phase output terminal “I” and quadrature output signal terminal “Q” of Alpha Correlator 36, are connected to the “I” and “Q” input terminals, respectively, of the Vector Modulator 2.

The output signal from the summer 10 at terminal 11 is representative of the “RF_OUT” RF signal from the linear amplification system. This output signal is also fed back to the multiplier 22 as one of its inputs. The other input to multiplier 22 is the carrier signal received at input terminal 12. The output of multiplier 22 is passed through a band pass filter 42 to provide the IF modulated signal Vo(t), which is provided as an input signal to an A/D converter 44, the digitized output of which is provided as an input signal to a Demodulator/Finite Impulse Response Low Pass Filter 46 which performs quadrature demodulation on the signals and outputs the complex, baseband digital signal, Vo(n), which is provided as another input signal to the Beta Correlator 38. The “I” and “Q” output terminals of the Beta Correlator 38 are connected to the “I” and “Q” input terminals of the Vector Modulator 16. The output of the Vector Modulator 16 is connected to the input of an error amplifier 48, the output of which is representative of the phase inverted and weighted amplified distortion products summed in summer 10 with the delayed and amplified distorted RF input signal. The amplitude and phase of the detected distortion products from error amplifier 48 have been adjusted for canceling the distortion products in the amplified distorted input signal, for providing the RF output signal having substantially reduced distortion products. Note that the delay 8, although shown as a separate delay component, is representative of the inherent delay in the power amplifier 6, and must be taken into account to insure that each distortion product in the amplified RF_IN signal (output of PA 6) arrives at summer 10 at the same time as their comparable processed, weighted, and phase inverted distortion products. Also note that the processing is made in the frequency domain.

More specifically, in the two loop feed forward system of FIG. 1, the error amplifier 48 amplifies detected distortion products of an appropriate phase for being at a level to effectively cancel the comparable distortion products appearing in a distorted RF input signal at summer 10. The Vector Modulator 16 acts to change the amplitude and phase of the detected distortion products to cancel these distortion products from the output, and to linearize the output. The amplification obtained from the error amplifier 48 is adjusted in correspondence to the amplified signal it receives from the Vector Modulator 16. The output of the Alpha Correlator 36 is fed to the Vector Modulator 2. This changes the phase and amplitude of the input to the power amplifier 6 to align it with the phase and amplitude of RF_IN, so as to provide cancellation of the carrier and data, and insure that the output of the summer 14 consists only of the distortion products.

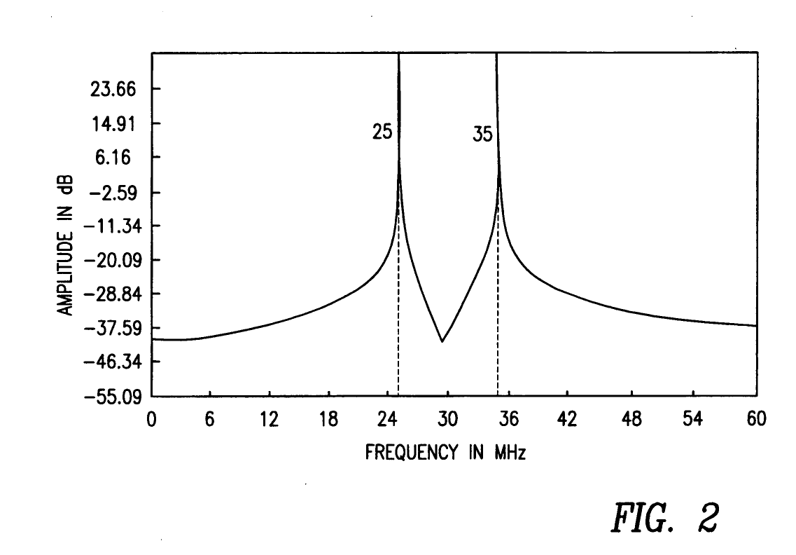

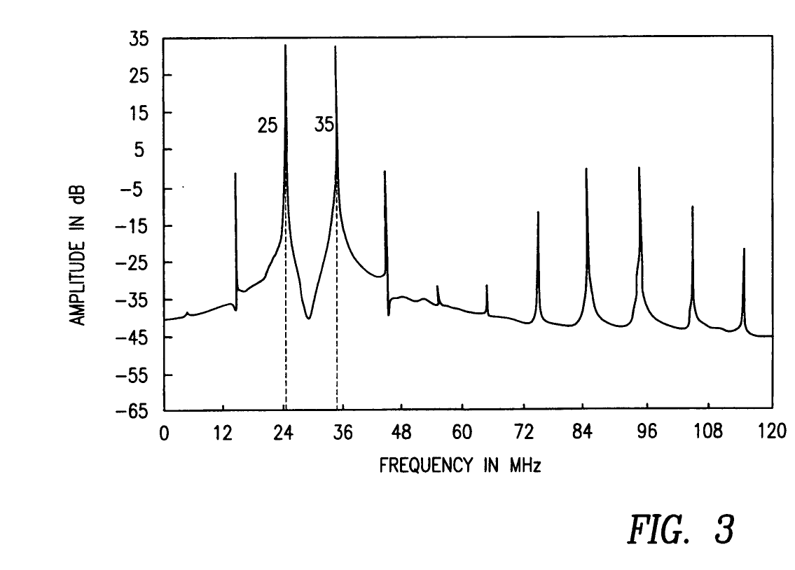

Operation of the system of FIG. 1 was provided via computer simulation to obtain the various waveforms of FIGS. 2 through 5. With reference to FIG. 2, an undistorted two-tone signal is shown, which signal in this example represents the carrier wave modulated by the tones. However, this modulated carrier wave signal is provided for purposes of illustration and example only, and is not meant to be limiting. Note that the undistorted carrier has peaks at 25 MHz and 35 MHz. FIG. 3 shows the signal of FIG. 2 to which distortion products have been added, such as may occur when the carrier is passed through a non-linear amplifier path, such as through power amplifier 6.

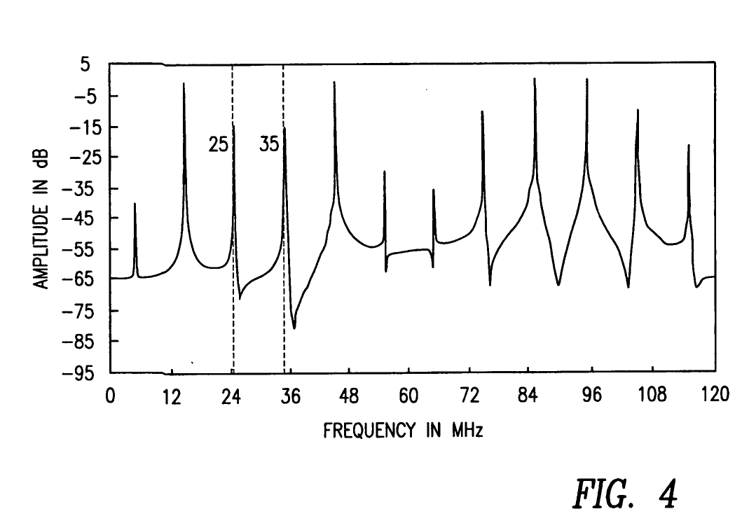

With further reference to the block schematic diagram of the two-loop Feed Forward System of FIG. 1, as previously mentioned, the components within the dashed box 53 are included in a “Beta Loop” and those within the dashed box 51 are included in what is known as an “Alpha Loop”. As shown, various of the components are common to each of the Alpha Loop 51 and Beta Loop 53. The function of the Alpha Loop 51 is to cancel and thus remove the carrier wave from the RF input signal with distortion products, for providing a detectable portion of the distortion products or signals for further processing. In FIG. 4, the results of passing the distorted signal of FIG. 3 through the Alpha Loop 51 provides the waveform of distortion products, which as shown are substantially low in amplitude, relative to the amplitude of the carrier wave. FIG. 4 shows the output of the summer 14.

The waveform of FIG. 4 is the output of the Alpha Loop 51. It is the distortion products with the desired information (carrier+data) removed or at least lowered to a level, which has minimal impact on the total power output. For example, assume that the total average output power is 20 watts, that 10 watts are in one of the two tones, and that 10 watts is in the other. Also assume that the distortion products are such that the third order tones are 10 dB less than the desired tones. If the output is not passed through the Alpha Loop 51, and the error amplifier 48 delivers 10 watts average power, this will lower the total output by many dB (infinite), but will not reduce the distortion products when compared to the desired two tones. Further assume that the Alpha Loop 51 reduces the desired two tones (or carrier+data) by 10 dB. The error amplifier 48 then delivers a signal with the power in the distortion products equal to the power in the distortion products of the associated amplifiers 6 and 48. Such operation, if properly adjusted, exactly cancels all of the distortion products. However, the power in the reduced desired two tones, in this example, will have an impact on the desired signal of still 3 dB. Allowing the Alpha Loop 51 to reduce the desired signal components by 20 dB relative to the distortion products lowers this impact to 0.92 dB, and at 30 dB the impact is 0.28 dB. The finer the adjustment of the Alpha Loop 51, the higher the level of the system output.

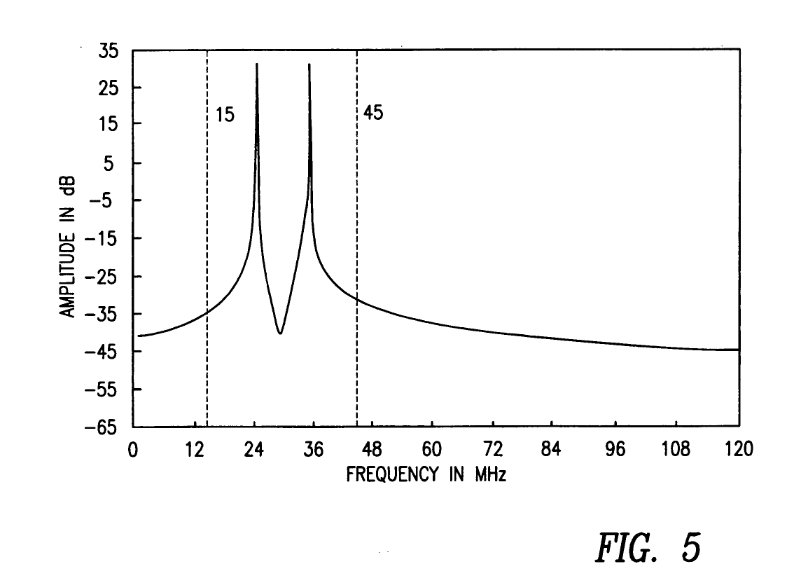

The function of the Beta Loop 53 is to amplify and phase adjust the distortion products for summing via summer 10 with the amplified distorted input signal RF_IN, for canceling out a substantial portion of the detected distortion products from the distorted input signal, thereby providing substantially reduced distortion products in the RF output signal, as previously described. An example of a resultant RF output signal appearing at terminal 11, in this example, is shown in FIG. 5. The comparison of the distorted input signal in FIG. 3 with that of the output signal of FIG. 5, illustrates the substantial reduction of the detected distortion products occurring below 24 MHz and above 35 MHz in the distorted input signal of FIG. 3.

Operation of the system of FIG. 1 will now be described in greater detail. The RF signal applied to terminal 4 is typically without distortion. The power amplifier 6 both amplifies and distorts the RF signal. For optimum operation, the distortion products must be removed to the greatest extent possible from the RF output signal appearing at terminal 11, in this example. Conventional systems can remove the distortion in one of two ways. The first way is known as predistortion where the undistorted signal, before the power amplifier 6 has a chance to change it, is purposely distorted in a manner opposite to the distortion created by the power amplifier 6, so that when it gets through the power amplifier 6 it becomes undistorted. The second way to do this is to take a distorted signal and remove the distortion products by canceling them with equal and opposite distortion products (products that have the same amplitude but are out of phase). The way conventional systems accomplish this is to have two loops, called an Alpha Loop and a Beta Loop. As previously described, Alpha Loop 51 looks at the signal coming out of the power amplifier 6, which can be designated as the error signal, for controlling weighting of the input signal to Vector Modulator 2. A Vector Modulator is a device that controls or weights the input signal in both amplitude and phase. By looking at the error, and comparing the error to the undistorted input signal, the Alpha Loop 51 then adjusts the amplitude and shifts the phase on the input signal to minimize the error output of summer 14. This occurs when the error signal is pure distortion. Alpha Correlator 36 drives the “I” and “Q” input terminals of Vector Modulator 2 to invert the input to the power amplifier 6 such that its output is 180° out of phase with the RF input signal. Also, a second loop called a Beta Loop 53 is required. The Beta Loop 53 again compares the undistorted input signal to the output signal at terminal 11, and controls the output from an error amplifier 48. The signal from the error amplifier 48 contains only distortion products. By adjusting or weighting the output from amplifier 48 via Beta Correlator 38 driving Vector Modulator 16, so that it cancels the distortion products in the output signal at terminal 11, an output signal with reduced distortion is obtained. The output signal is the predistorted signal that has come through the power amplifier 6, and applied to summer 10, for summing with the weighted distorted and proper phase inverted signal from the error amplifier 48, to provide a relatively distortion free output signal at terminal 11. The Alpha and Beta Loops 51, 53, respectively, work together. If the predistortion is not used, the level of distortion in the output signal at terminal 11 that needs canceling might be high, requiring that the level of the signals required to sum with the distortion products be high, whereby the error amplifier 48 would have to be large. While prior systems function this way, it's not a great advantage because the error amplifier 48 required is almost as large as the power amplifier 6 it is desired to linearize. By having the predistortion on the input signal, the distortion products in the output are reduced to some extent, whereby the error amplifier 48 used to cancel output signal distortion and gain a larger amount of distortion free dynamic range in the output signal at terminal 11 is a smaller amplifier then would otherwise be required.

The present invention is useful in military radio communication systems, for example, that operate over a wide range of frequencies, typically from about 20 MHz (megahertz) to over 2 GHz (gigahertz). Typically, the comparator in the output loop is trying to process the distortion products that are very low in the presence of the carrier with its modulation, and as the distortion products are reduced to a reasonable level, the interference from the carrier in the control loop becomes overwhelming. As a result, one needs a filter to remove the carrier and its normal products, so that only the distortion products are left to compare with the undistorted input signal, to obtain the correct error signal. Conventionally, for example in cellular systems, a fixed filter provides the filtering. Military systems don't have the option of having a fixed filter, since systems that operate over a very wide frequency band or use frequency hopped signals, require a frequency agile filter.

In the prior linearized RF amplifier system of FIG. 1, manual tuning of complex weighting factors must be made in order to minimize the detected distortion products. To make the system practical, automatic adjustment of the Alpha and Beta Loops 51, 53, respectively, is required. Also, note further that the RF output signal shown in FIG. 5, as derived from the linear amplifier system of FIG. 1, does still include distortion products, but they are not visible in the waveform since their level is 40 to 50 dB below the level of the carrier wave.

One method attempted in the prior art for automating adjustment of the loops is by feeding the sum signals to one side of a correlator, for comparing the sum signals with an undistorted signal, for obtaining the proper weighting. Complex LMS (Least Mean Square) algorithms used in programming the correlators along with controlling the Vector Modulators, provide control of the weighting factors.

In the system of FIG. 1, the summed signals must be filtered to remove the carrier. If the carrier is not removed, the system will lack sensitivity because it will be comparing carriers to carriers, and trying to minimize distortion products that are 100,000 to 1,000,000 times lower in amplitude than the carrier itself. With further reference to FIG. 5, as previously indicated the waveform illustrates that although the distortion products are still present, they are not resolvable for the reasons indicated. For these reasons, using a correlator as previously indicated, cannot overcome this difficulty. In order to successfully correlate the distortion products, it is necessary that the carrier products be lowered or reduced in amplitude, to permit detection and processing of the low level distortion products. To accomplish this for narrow band signals, it may be possible to use a notch filter tuned to the carrier frequency. However, with a multi-octave amplifier, a notch filter is not feasible, for at least two reasons. The first is because of the wide frequency range required, and the second is because of the need to tune the filter. Any such tuning will likely have to be accomplished very rapidly, if the signal rapidly changes frequency, such as with frequency hopping. For example, the system of FIG. 1 is not practical for use in military tactical radios requiring a linear amplifier capable of operating at full power from 20 MHz to 2 GHz, and all bands of legacy radios.

As will be described below, the present inventive linearized RF amplifier system uses a Gamma Loop to remove or extract the carrier and data from the combined output of carrier and data of a Beta Loop. In effect, the Gamma Loop represents an electrically tunable notch filter, the output of which provides a reference for a Beta Correlator, to permit the Beta Correlator to compare distortion products in the processed signal against high and low level distortion products in the actual distorted input signal.

As discussed above, a circuit schematic block diagram is shown in FIG. 6 for the linear amplifier system of the present invention. Many of the components are similar to and are connected together as in the amplifier of FIG. 1. However, certain components have been arranged differently, and additional components have been added, as will be explained. The Vector Modulator 2, instead of having its output connected to the power amplifier 6, now has its output connected to one input of the summer 14. The input of power amplifier 6 now directly receives the RF_IN signal. The multiplier 22 still receives on one input the carrier signal, but its other input is now connected to the output of a summer 54, which has been added. Also the output of the Demodulator/Finite Impulse Response Low Pass Filter 46 is now connected to both one input of Beta Correlator 38, and also to one input of a Gamma Correlator 56. The other input of the Beta Correlator 38 is now connected to the output of the Demodulator/Finite Impulse Response Low Pass Filter 32. The other input of the Gamma Correlator 56 is connected to the output of the Demodulator/Finite Impulse Response Low Pass Filter 40. The Demodulator/Finite Impulse Response Low Pass Filter 34 of the prior linear amplifier system of FIG. 1 is not included in the linear amplifier system of FIG. 6. The “I” and “Q” output terminals of the Gamma Correlator 56 are connected to the “I” and “Q” terminals, respectively, of the Vector Modulator 52. The input of the Vector Modulator 52 is connected to input terminal 4 for receiving the distorted radio frequency input signal RF_IN. The output of the Vector Modulator 52 is connected to an inverting input of the summer 54, a non- inverting input of which is connected to output terminal 11. The components of the Alpha Loop are essentially those enclosed in the dashed Box 60, those of the Beta Loop in dashed Box 62, and those of the Gamma Loop in dashed Box 64. Others of the dashed boxes include components shared by two or more loops, as indicated.

In comparing the arrangement of the Vector Modulator 2 in FIG. 1 relative to FIG. 6, there are differences, which will now be described. In order to isolate the distortion products produced by the power amplifier 6, RF_IN and the output signal from amplifier 6 have to be exactly 180° out of phase when they enter the summer 14 so that the signals cancel each other out, leaving just the distortion products as the error signal. Since there is a phase delay in the amplifier 6 (represented by delay element 8 which is really inherent in amplifier 6), the Alpha Loop 60 uses Vector Modulator 2 to rotate one of the signals 180° in phase. In FIG. 1, the input signal to the amplifier signal 6 is rotated, which rotates the output of the amplifier 6 prior to it going into summer 14. In FIG. 6, RF_IN is rotated prior to entering the summer 14. It doesn't matter which signal is rotated, as long as the two signals applied to summer 14 are 180° out of phase. Accordingly, the Vector Modulator 2 can be arranged alternatively in FIG. 6 to correspond to its arrangement in FIG. 1.

Operation of the present RF broadband linearized amplifier of FIG. 6 will now be described. The Alpha Loop 60, operating on a distorted two tone signal as shown in FIG. 3, for example, provides partial cancellation of the carrier from the input signal for exposing some of the distortion products at a dB level lower than that of a carrier, as in the system of FIG. 1 and as illustrated in FIG. 4. However, the Gamma. Loop 64 provides extraction or removal of the carrier and data from the sum or combined signals of the carrier plus data plus distortion products of RF_OUT of the power amplifier 6, and the amplified and rotated distortion products of the Beta Loop 62 as provided by the Gamma Correlator 56. The output of the Gamma Correlator 56 is then provided to the Beta Correlator 38 in the form of a reference signal Vo(n). More specifically, the reference signal is Vo(n) as formed by the “I” and “Q” output signals from Gamma Correlator 56 driving the “I” and “Q” input terminals of Vector Modulator 52, for modulating or rotating the RF_IN input signal. The vector modulated RF_IN signal is applied to summer 54 for subtraction from the RF_OUT signal, with the output of summer 54 being applied to multiplier 22 for multiplication with the reference signal, for converting the signal from RF to baseband (an intermediate frequency or IF signal). The product, or output, from multiplier 22 is then passed through, and processed by, the series connected low pass filter 42, which outputs the IF modulated signal Vo(t), which is input to A/D 44, converting the signal to the digital domain. The digitized signal is then quadrature demodulated by the Demodulator/Finite Impulse Response Low Pass Filter 46. The output of the latter is the complex baseband reference signal Vo(n). The Gamma Correlator 56 operates automatically, and requires no manual input or control. Note that there is a second input to the Gamma Correlator 56, shown as Vm(n). The Gamma Correlator 56 compares the Vm(n) input containing the desired signal to the Vo(n) input, and operates to reduce the Vm(n) components supplied to the Beta Correlator 38. The Beta Correlator 38 compares this reference signal Vo(n) of high and low level distortion products provided by the Gamma Loop 62 processed signal against the actual distorted input signal, for driving Vector Modulator 16 to rotate or adjust the phase of the distortion products. Accordingly, Beta Loop 62 operates to apply properly weighted or amplified and phase reversed distortion products to summer 10 for substantially canceling the distortion products from the RF_OUT output signal.

As indicated, the present invention overcomes the disadvantages of the prior art by adding a third loop, herein designated the Gamma Loop 64 (see FIG. 6). The Gamma Loop 64 essentially takes the undistorted input signal, and sums it with the sum of the output from the power amplifier 6 and the error amplifier 48 so that it cancels the undistorted portion of the output signal (the carrier as modulated). By canceling the undistorted portions of the output signal, only the distortion products remain. The distortion products then go into the Beta Correlator 62, and they form the basis for controlling the amplitude and phase of the distortion products amplified by error amplifier 48 for canceling the distortion products.

With further reference to FIG. 6, the signal applied to terminal 12 is an undistorted signal containing carrier and possibly data, whereas the RF signal applied to input terminal 4 is the carrier plus the signal or data information it's carrying plus noise and the distortion added by any earlier amplification processes. The Vector Modulator 2 rotates the RF input signal to provide a signal at 180° (more or less) by virtue of receiving the “I” and “Q” signals from the Alpha Correlator 36. Note that although the system is shown with digital conversion and digital processing, it can be performed in analog manner, whereby the analog-to-digital converters 26 and 30 would be eliminated, and the filters and demodulators 32 and 40 would be analog instead of digital. Similarly, the Alpha Correlator 36 would be an analog correlator instead of a digital correlator. The Alpha Correlator 36 acts to compare its two input signals Ve(n) and Vm(n) to provide the “I” and “Q” output signals to the Vector Modulator 2, for operating the Vector Modulator 2 to rotate the input signal it receives from terminal 4 by phase inverting the signal by 180°, and for outputting the rotated signal to the summer 14.

As previously indicated, Gamma Loop 64 is operating on the carrier and on the signal out of the power amplifier 6 plus the summed output from the error amplifier 48 compared to the carrier to remove the carrier component from the output signal before it is inputted into the Beta Correlator 38 so that the latter correlator then is operating on the distortion products without the carrier. The Gamma Correlator 56 drives Vector Modulator 52 to adjust the phase of the latter's output signal applied to summer 54 for summing with the RF_OUT output with the carrier and all distortion products (at terminal 11), against the carrier, so that the carrier is removed. The distortion products represented by Vo(n) are applied to Beta Correlator 38. The reference Vo(n) for the Gamma Correlator 56 is the undistorted reference signal multiplied by the output from summer 54 that is provided via components 22, 42, 44 and 46 providing a filtered digital baseband signal. The input signal Vo(n) to the Gamma Correlator 56 is in essence a feedback signal for providing the Gamma Correlator 56 nulling information that the carrier has been nulled out of the output signal for processing, and that the signal to the Beta Correlator 38 will then ultimately be only distortion products. In summary, the Gamma Correlator 56 acts to remove the carrier and present only distortion products to the Beta Correlator 38 for comparison with Ve(n), that contains the amplified and distorted input signal, for driving the Vector Modulator 16 to modify the input signal it receives for driving the low power amplifier 48 to have the distortion products at the appropriate level and phase for summing in summer 10 for removal of the distortion products from the RF output signal, thereby providing a substantially undistorted output signal. The use of the Gamma Correlator 56 in conjunction with the Beta Correlator 38, in accordance with the invention, provides for permitting the power amplifier 6 to be ten watts, for example, and the error amplifier 48 to be perhaps only one watt, over a very wide range of frequencies unlike what can be provided in the prior art. This represents a primary advantage of the present invention relative to the prior art.

In summary, in the present invention the Alpha Loop 60 removes the carrier wave from the output signal of power amplifier 6, to produce a signal containing only distortion products or components. The Beta Loop 62 operates to compare the original RF input signal with both carrier and distortion components, to weight the distortion components in phase and amplitude, and combine them with the original output signal to provide an output signal having only the amplified carrier wave as modulated by data or information. The Gamma Loop 64 enhances the ability of the Beta Loop 62 to operate to eliminate even very low level distortion products or components by extracting the carrier wave and data or information from RF_OUT to provide only the actual distortion products, to permit the Beta Loop 62 to compare the distortion products in the processed reference signal against the actual distortion components.

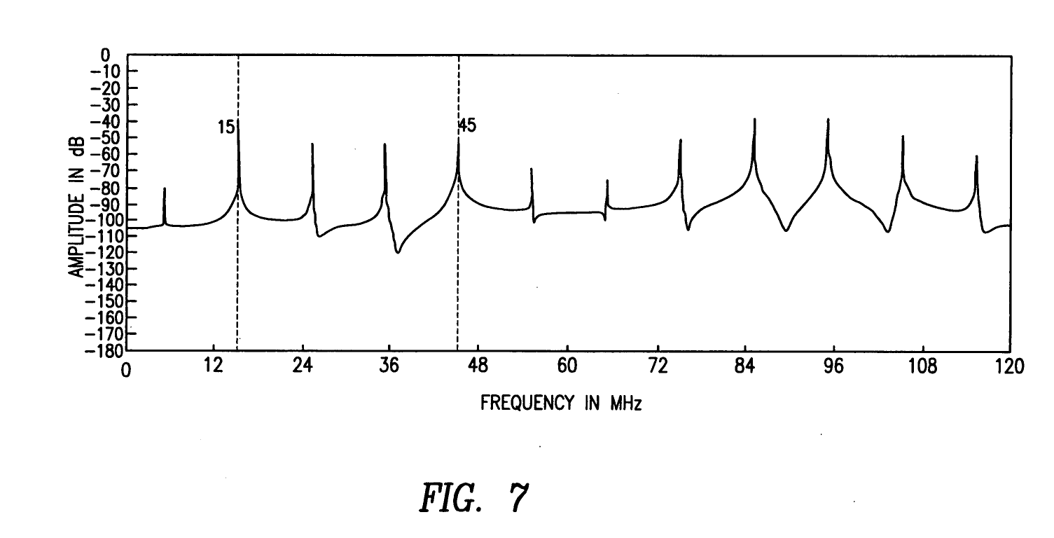

The improvements provided by the present three loop feed forward linearized amplifier system can be readily seen by comparing the dB levels of the distortion products left in the output signal RF_OUT through use of the two loop feed forward linear amplifier system of FIG. 1, as compared to the level of distortion products in the output through use of a three loop feed forward linear amplifier system of FIG. 6. Note particularly, as shown in FIG. 4, in the two loop feed forward system the distortion products available for cancellation range from −5 dB to −75 dB, whereas in the present three loop feed forward system the available distortion products range from −40 dB to −110 dB (See FIG. 7). Note that the higher ranges of cancellation require a precision which may not be practical. Also, note that the waveforms of FIGS. 2 through 5 and 7 were obtained through computer simulation, as previously mentioned. Further note that various components are shared between the Alpha Loop 60, Beta Loop 62, and Gamma Loop 64.

Note that the Alpha Correlator 36, Beta Correlator 38, and Gamma Correlator 56, in this example, are each provided by field programmable gate arrays (FPGA). Each is programmed to provide the desired functions. An off-the-shelf FPGA that can be used for the aforesaid correlators is an Altera Flexlok 100. Also, the FIR Filters 32, 40, and 46 can each be provided by an off- the shelf Gray Chip Filter. The off-the-shelf components are given for purposes of example only, and are not meant to be limiting, whereby other manufacturers' components or devices can also be utilized for providing the necessary functions.

The present linearized wide band RF amplifier of FIG. 6 can be used in modern communication systems, universal radios, and so forth, that require operation in a frequency range from below about 20 MHz to above about 2 GHz, covering all bands of legacy radios. In linearized amplifiers, the power amplifier is the limiting factor. The present system permits the power amplifier to operate at full power over a wide band of frequencies, via avoidance of use of a notch filter.

Although various embodiments of the present invention have been shown and described, they are not meant to be limiting. Those of skill in the art may recognize certain modifications to these embodiments, which modifications are meant to be covered by the spirit and scope of the appended claims.

1. A broadband linearized RF amplifier comprising:
a power amplifier for receiving and amplifying a relatively undistorted RF input signal provided by a modulated carrier wave, wherein the RF output signal from said power amplifier contains distortion products generated in amplifying the input signal;
a source of reference carrier wave;
Alpha Loop means for processing the input and output signals to produce a first reference signal having processed distortion products at a dB level lower than that of the carrier;
Gamma Loop means for processing the reference carrier wave and distorted output signal from said power amplifier, to remove the carrier wave from the output signal and produce a second reference signal containing only distortion products occurring in the RF output signal; and
Beta Loop means for comparing said first and second reference signals to produce properly weighted, phase adjusted, and amplified distortion products, for summing with the distorted output signal from said power amplifier, to cancel the distortion products from the output signal.

2. The amplifier of claim 1, wherein said Beta Loop means cancels distortion products ranging from about −5 dB to about −110 dB relative to the reference carrier wave.

3. The amplifier of claim 1, wherein said Alpha Loop means includes:
a first Vector Modulator for receiving and phase inverting said RF input signal in response to signals received at in-phase “I” and quadrature “Q” input terminals thereof, and providing an output signal that is 180° out of phase with said RF input signal;
a first summer for producing an output signal that is the sum of the output signal from said power amplifier and the output signal from said first Vector Modulator;
a first multiplier for multiplying the output signal from said first vector multiplier with the unmodulated carrier wave to produce a first product signal;
first low pass filter means for filtering said first product to produce a first filtered signal;
a second multiplier for multiplying the output signal from said first summer with the unmodulated carrier wave to produce a second product signal;
second low pass filter means for filtering said second product signal to produce a second filtered signal; and
first correlator means for correlating said first and second filtered signals to produce in-phase “I” and quadrature “Q” output signals for driving and connection to the “I” and “Q” input terminals, respectively, of said first Vector Modulator.

4. The amplifier of claim 3, wherein said first low pass filter means includes:
a first band pass filter having an input connected to an output of said first multiplier;
a first analog-to-digital (A/D) converter having an input connected to an output of said first low pass filter; and
a first demodulator/finite impulse response low pass filter having an input connected to an output of said first A/D converter, and an output connected to both a first input of said first correlator means, and a first input of said Gamma Loop means.

5. The amplifier of claim 4, wherein said second low pass filter means includes:
a second band pass filter having an input connected to an output of said second multiplier;
a second A/D converter having an input connected to an output of said second low pass filter; and
a second demodulator/finite impulse response low pass filter having an input connected to an output of said second A/D converter, and an output connected to both a second input of said first correlator means, and a first input of said Beta Loop means.

6. The amplifier of claim 5, wherein said Gamma Loop means includes:
a second Vector Modulator for receiving and phase inverting said RF input signal in response to signals received at “I” and “Q” input terminals thereof, to provide an output signal representative of the phase inverted RF input signal;
a second summer for producing an output signal that is the sum of the output from said second Vector Modulator and an RF output signal from said linearized amplifier;
a third multiplier for multiplying said unmodulated carrier wave with the RF output signal from said linearized amplifier to produce a third product signal;
a third low pass filter means for filtering said third product signal to produce a third filtered signal; and
second correlator means for receiving and correlating said first and third filtered signals to produce “I” and “Q” output signals for driving and connection to the “I” and “Q” input terminals, respectively, of said second Vector Modulator, for nulling to zero the carrier wave in said third filtered signal.

7. The amplifier of claim 6, wherein said Beta Loop means includes:
a third Vector Modulator for receiving and phase inverting the output signal from said first summer in response to signals received at “I” and “Q” input terminals, thereof, for producing an output signal representative of the distortion products occurring in the RF output signal from said linearized amplifier that are 180° out of phase with the latter;
a third correlator for receiving and correlating said first and third filtered signals to produce “I” and “Q” output signals for driving and connection to the “I” and “Q” input terminals, respectively, of said third Vector Modulator;
a error amplifier for receiving the output signal from said third Vector Modulator, for amplifying the same to produce an output signal containing distortion products of substantially the same amplitude but 180° out of phase with the distortion products in the RF output signal from said linearized amplifier; and
a third summer for receiving and summing the output signal from said power amplifier with the output signal from said error amplifier, for producing an RF output signal from said linearized amplifier that is substantially free of distortion products.

8. The amplifier of claim 7, wherein the wattage of said error amplifier is small relative to the wattage of said power amplifier.

9. The amplifier of claim 7, wherein said Alpha, Beta, and Gamma correlators are each provided by field programmable gate arrays.

10. The amplifier of claim 1, wherein said linearized RF amplifier is operable at full power of said power amplifier over a frequency range from about 20 MHz (megahertz) to about 2 GHz (gigahertz).

11. A method for providing a broadband linearized RF amplifier system comprising the steps of:
amplifying via a power amplifier an undistorted RF input signal, whereby the amplified RF output signal includes a modulated carrier with distortion products produced during amplification;
removing the modulated carrier from the RF output signal to obtain a comparison signal containing only the distortion products;
phase inverting by 180° the distortion products in the comparison signal;
dynamically adjusting the phase inverted distortion products to have the same amplitude as the distortion products in the amplified RF output signal; and
summing the phase and amplitude adjusted distortion products with the amplified RF output signal to produce an RF output signal from said RF amplifier system that is substantially free of distortion products.

12. A method for providing a broadband linearized RF amplifier system comprising a power amplifier that amplifies an RF input signal and produces a first output signal containing distortion products added to the RF input signal during the amplification process, the method comprising the steps of:
processing the RF input signal and said first output signal from said power amplifier to produce a first processed signal containing only said distortion products;
summing together the first output signal from said power amplifier with an output signal from an error amplifier to provide an RF second output signal from said RF amplifier system;
processing the RF input signal, said second output signal, and a reference carrier wave, to remove the carrier wave from said second output signal and to produce a second processed signal containing only said distortion products; and
processing said first and second processed signals for producing a third processed signal containing phase adjusted distortion products for amplification by said error amplifier to cause said distortion products to be canceled from said second output signal.
